(19) United States
(12) Patent Application Publication
(10) Pub. No.: US 2002/0160620 A1
(43) Pub. Date: Oct. 31, 2002

(54) Method for producing coated workpieces, uses and installation for the method

(76) Inventors: Rudolf Wagner, Fontnas (CH); Siegfried Wiltsche, Feldkirch (AT); Juergen Ramm, Sevelen (CH)

Correspondence Address: EVENSON, McKEOWN, EDWARDS & LENAHAN, P.L.L.C., 1200 G Street, N.W., Suite 700, Washington, DC, 20005, US

(21) Appl. No.: 09/792,055

(22) Filed: Feb. 26, 2001

(51) Int. Cl. H01L 21/31; H01L 21/469

(52) U.S. Cl. 438/758

(57) ABSTRACT

A method of manufacturing electronic or opto-electronic or micromechanic components by providing a vacuum where the external surface of a wall is exposed to ambient air and the inner surface enclosed as a processing area. A base body of a part to be manufactured is introduced into the processing area and a low energy plasma discharged is generated in the process area, the ion energy at the surface of the base body is between 0 and 15 eV in order to introduce a reactive gas. Subsequently, the reactive gas treats the base body in order to separate the processing area from an inner surface of the wall and enclosing the processing area during the treatment.

The present invention relates to a method for producing coated workpieces according to the preamble of claim 1, to uses therefor according to claims 28 to 35, to an installation for implementing the above-mentioned method according to the preamble of claim 36 and to uses therefor according to claims 51 to 54.

The present invention is based on problems which occur during the manufacturing of thin layers by means of CVD and PECVD methods. The findings made in this case, according to the invention, can be applied particularly to the production of semiconductor layers, for example, when producing solar cells or modulation doped FETs or hetero-bipolar transistors.

Thin semiconductor films are deposited either in a monocrystalline form, that is, epitaxially, on an also monocrystalline substrate, such as a silicon substrate, or are deposited in a polycrystalline form or amorphous form on polycrystalline or amorphous substrates, such as glass. Although in the following the invention will be described mainly with respect to the production of silicon-coated and/or germanium-coated substrates, it may, as mentioned above, also be used for the production of other workpieces and workpieces coated with other materials.

Known methods for depositing epitaxial semiconductor films are:

Molecular beam epitaxy (MBE),

chemical vapor deposition (CVD),

remote plasma enhanced CVD with DC or HF discharge,

electron cyclotron resonance plasma-assisted CVD. (ECRCVD).

“CVD method” is a collective term for a large number of thermal deposition methods which differ either in the construction of the assigned apparatuses or in their operating mode. Thus, for example, a CVD method can be carried out at a normal atmospheric pressure or at much lower pressures down into the range of the ultra high vacuum. Reference can be made in this respect to (1) as well as to (2).

In the commercial production of epitaxial Si layers, only CVD is normally used. In this case, the applied reactive gases are silicon-containing gases, such as silane chlorides, SiCl₄, Si,HCl and SiH₂Cl₂ as well as silanes, such as SiH₄, or Si₂H₄. Characteristics of the standard CVD methods are the high deposition temperatures in the order of 1,0000° and more, as well as pressures of typically 20 mbar to 1,000 mbar, that is, to normal atmospheric pressure.

According to the process conditions, coating rates of several μm per minute can be achieved in this manner. corresponding to several 100 Å/sec., with respect to which reference is again made to (1).

In contrast, low pressure chemical vapor deposition (LPCVD), which is synonymous with low pressure vapor phase epitaxy (LPVPE), takes place at pressures below 1 mbar and permits lower process temperatures to typically 7000° C. In this respect, reference is made, in addition to (1), also to (3) and (6).

With respect to the LPCVD and with reference to (6), at a deposition temperature of 650° c., a growth rate of

GR=50 Å/min

is indicated. This takes place at a reactive gas flow for silane of

F=14 sccm.

This results in a characteristic number which is relevant to the gas yield, specifically the growth rate per reactive gas flow unit GR_{F} at

GR_{F}=3.6 Å/(sccm·min)

On 5″ wafers, corresponding to a surface

A_{S}=123 cm²,

converted from the actual surface A₂ for 2″ wafers, a deposition quantity (growth amount) GA is obtained at

GA=5.2·10¹⁴ Si atoms/sec.

Again, with respect to a reactive gas flow unit, the characteristic number “deposition quantity per reactive gas flow unit”, in the following called “gas utilization number”, GA_{F} is obtained at

GA_{F}=8.4·10⁻³,

corresponding to 8.4 o/oo.

At 650°, an epitaxial layer is formed.

If the deposition temperature is reduced to 600° C., a polycrystalline layer is formed. In this case, the following applies:

GR=3 Å/min

F=28 sccm silane

GR_{F}=0.11 Å/sccm/min)

GA=3.1·10¹⁵ Si atoms/sec on A_{R}

GA_{F}=2.5·10⁻⁴, corresponding to 0.25 o/oo.

Basically, the following criteria are required for a defect-free epitaxial layer growth:

In the case of transmission electron microscopy on cross-sectional preparations, the proof of epitaxy is established by electron diffraction and high resolution.

In the area of 10 to 15 μm, which in this case can typically be penetrated by radiation, along the boundary surface to the substrate, no defects must be visible. Typical enlargements in the analysis of defects are 110′000 to 220′000.

Another development is the ultra high vacuum chemical vapor deposition (UHV-CVD) with working pressures in the range of 10⁻⁴ to 10⁻² mbar, typically in the range of 10⁻³ mbar, with respect to which reference is made to (4) as well as to (5), (7). It permits very low workpiece temperatures; however, the growth rates or coating rates being extremely low; thus, for example, approximately 3 Å/min for pure silicon at 550° C. according to (5).

The reason for the low growth rates is the fact that the absorption rate and decomposition rate of the reactive molecules, thus, for example, of SiH₄, decreases with an increasing hydrogen coating of the workpiece surface. The layer growth is therefore limited by the desorption rate of H₂, which, however, rises exponentially with the temperature. In this respect, reference is made to (8). Because of the lower bonding energy of the Ge—H bonding in comparison to the Si-H bonding, the hydrogen desorption of an Si—Ge alloy surface is higher, so that, while the substrate temperature is the same, a higher growth rate is obtained than in the case of pure Si; for example, at a content of 10% Ge by a factor 25 at 550° C. (5).

Another possibility of achieving high deposition rates of an epitaxy quality at low substrate temperatures consists of (9) decomposing the reactive gases by means of a u-wave plasma (ECRCVD).

By the use of plasma sources, which are based on the principle of electron cyclotron resonance, the incidence of high-energy ions onto the substrate is to be avoided.

As a rule, such sources operate in the pressure range of 10⁻³ to 10⁻⁴ mbar, which, however, results in larger free path lengths than in the case of capacitively coupled-in high-frequency Hf plasmas. This, in turn, can lead to an undesirable ion bombardment of the substrate and thus to the generating of defects, as indicated in (10). The energy of the ions impacting on the substrate, however, can be limited by an external control of the substrate potential, whereby ion-related damage can largely be avoided. Also by means of the ECRCVD method, the growth rates for pure silicon, as a rule, amount only to a few 10 Å/min, at low deposition temperatures ≦600° C.

Summarizing, this results in the following:

Layers which are deposited with a quality which is suitable also for the depositing of epitaxial layers can be deposited at deposition temperatures≦up to now:

by UHV-CVD with growth rates GR of approximately 3 Å/min or

ECRCVD with a growth rate GR higher by approximately 1 order (30 Å/min)

PECVD methods, whose plasmas are produced by DC discharges, could be used for the manufacturing of layers of epitaxy quality—that is, a correspondingly lower fault density (see above)—neither for the construction of epitaxial nor for the construction of amorphous or polycrystalline layers; at least not with a growth rate GR, reliability and efficiency to be ensured for industrial manufacturing.

On the other hand, the use of capacitively coupled-in high-frequency fields for generating HF plasmas for PECVD methods was reported very early, with respect to which reference is made to (11). The difficulty of this approach is the fact that not only the reactive gases are decomposed in such Hf plasmas. Simultaneously, the substrate surface is exposed to an intensive bombardment of highly energetic ions, as utilized specifically also in the case of reactive atomizing or high-frequency etching. This, on the one hand, promotes the hydrogen desorption but, simultaneously results in defects in the growing layers. A method, which is modified in this respect, the RPCVD—remote plasma chemical vapor deposition—takes this into account in that the substrates to be coated are not exposed directly to the HF plasma, which leads to better results (12). However, the achieved growth rates are low, specifically usually fractions of nm per minute to no more than several nm per minute according to (13).

It is an object of the present invention to indicate a method which can be used in industrial manufacturing and which permits the growing of layers of an epitaxy quality which have significantly higher growth rates than previously known.

This is achieved by means of methods of the initially mentioned type which are characterized according to the characterizing part of claim 1 and by a system which is characterized according to the characterizing part of claim 36. Preferred embodiments of the method are specified in claims 2 to 27; preferred embodiments of the system are specified in claims 37 to 50. The method according to the invention is particularly suitable for the manufacturing of semiconductor-coated substrates with an epitaxial, amorphous or polycrystalline layer, in this case particularly of Si, Ge or Si/Ge alloy layers as well as Ga or Ga bonding layers.

In this case, particularly also doped semiconductor layers can be deposited; layers containing silicon and/or germanium, doped preferably with at least one element of Groups III or V of the classification of elements or layers containing gallium with at least one element of Groups II, III, IV or VI of the classification of elements, for example, with Mg or Si.

Concerning the initially discussed coating techniques for producing epitaxial layers, the following can be summarized:

The CVD methods, particularly the UHV-CVD methods, lead to excellent layer qualities even at substrate temperatures below 500° C. They are therefore suitable for also producing epitaxial layers, where extremely high demands are made on the layer quality. However, in the case of this method, the growth rate, for example, for Si, is extremely low, as mentioned above, in the order of 3 Å/min at 550° C.

Microwave-plasma-assisted methods, ECRCVD, have the advantage that the decomposition of the reactive molecules can take place without high thermal energy. The ion bombardment of the substrate leads to an increased hydrogen desorption. Both effects can result in a considerable increase of the growth rate. However, at low temperatures, unacceptably high defect densities are observed which are induced by the ion bombardment. Although a control by way of the substrate bias voltage increases the layer quality, it does not change the comparatively low rates.

Thus, there seems to be an inherent contradiction: An ion bombardment of the substrate, on the one hand, leads to an increased growth rate because of an increased hydrogen absorption, but simultaneously increases the defect density.

The following picture exists according to (2) for thermal CVD methods operated at atmospheric pressure:

Si growth rate GR: 2×10⁻³ nm/min (at 600° C., measured 3·10⁻² and converted to 550° C.)

Gas flow, SiCl₂H₂, F: 100 sccm.

This results in a growth rate GR per SiCl₂H₂ flow unit, GR_{F}≈2×10⁻⁴ Å/(sccm.min).

A gas flow F of 100 sccm SiCl₂H₂ corresponds to 4.4×10¹⁹ molecules/sec.

The growth rate GR of 2×10⁻³ nm/min corresponds to a growth rate of 2×10⁻⁴ silicon monolayers per second on an S″ wafer, corresponding to a surface A₅ of 123 cm². Thus, on the total surface, a deposited quantity of

GA=1.7×10¹³ silicon atoms/sec.

is obtained per second. By relating the silicon quantity deposited per second and the reactive gas quantity admitted per second, the gas utilization number GA_{F} is obtained at

GA_{F}=3.9×10⁻⁷ .

This corresponds to a utilization of approximately 0.0004 o/oo.

We note that, at atmospheric CVD, the following is obtained:

GR_{F≈}2×10⁻⁴ Å/(sccm.min)

GA_{F}≈0.0004 o/oo.

From (5), combined with (4) and (7), the following estimate is obtained for UHV-CVD:

GR_{F}≈0.1 Å/(sccm.min) and

GA_{F}≈0.0035 corresponding to approximately 35 o/oo.

The above concerns the methods which so far have been used industrially for the production of epitaxy quality layers.

From German Patent Document DE-OS 36 14 384, a PECVD method is known in which DC glow discharge in the form of a low-voltage discharge is used. As the result, layers which have particularly good mechanical characteristics are to be deposited rapidly, that is at a high growth rate.

A cathode chamber with a hot cathode communicates with a vacuum recipient by way of a diaphragm. An anode is provided opposite the diaphragm. In parallel to the discharge axis formed between the diaphragm and the cathode, an inlet arrangement is provided for a reactive gas. Workpieces are arranged opposite this arrangement with respect to the discharge axis. With respect to the anode potential, discharge voltages U_{AK} below 150 V are applied, and the discharge is operated with a current intensity I_{AK} of at least 30 A. For the coating, the workpieces are brought to negative potentials between 48 and 610 V.

The tests illustrated therein result in the following picture:

| Example | GR(Å/min | GR_{F}(Å/(sccm.min)) |
|---|---|---|
| 1 | 10¹ | 2.5 |
| 2 | 380 | 1.2 |
| 3 | 2 × 10³ | 2.5 |
| 4 (Si) | 166 | 0.7 |
| 5 | 466 | 1.2 |
| 6 | 750 | 0.7 |
| 7 | 250 | 0.5 |
| 8 | 500 | 0.75 |
| 9 | 316 | 0.38 |
| 10 | 344 | 0.18 |
| 11 | 62 | 0.18 |
| 12 | 58 | 0.14 |

The present invention is now based on the recognition that workpiece coatings can be carried out which have a layer quality which meets the demands made on epitaxy layers in that, for this purpose, in contrast to previous expectations, a non-microwave-plasma PECVD method is used—that is, a PECVD method with DC discharge—and specifically a PECVD method as known, with respect to its principle, from German Patent Document DE-OS 36 14 348. As will be illustrated, it will be possible to achieve in epitaxy quality:

a) Growth rates GR of at least 150 Å/min, even of at least 600 Å/min;

b) GR_{F} of at least 7.5 Å/(sccm.min), or even 40 Å/(sccm.min), preferably even 75 Å/(sccm.min), and further

c) gas utilization numbers GA_{F} at least in the range of 5%.

It is recognized that, in the case of the DC-PECVD method used according to the invention, the plasma discharge leads to the lowest-energy ions, also to the lowest-energy electrons, but that the charge carrier density, particularly the electron density at the utilized discharge is very high.

In the following, the invention will be explained by means of figures on the basis of examples.

FIG. 1 is a schematic view of a first preferred embodiment of a system according to the invention for implementing the method according to the invention;

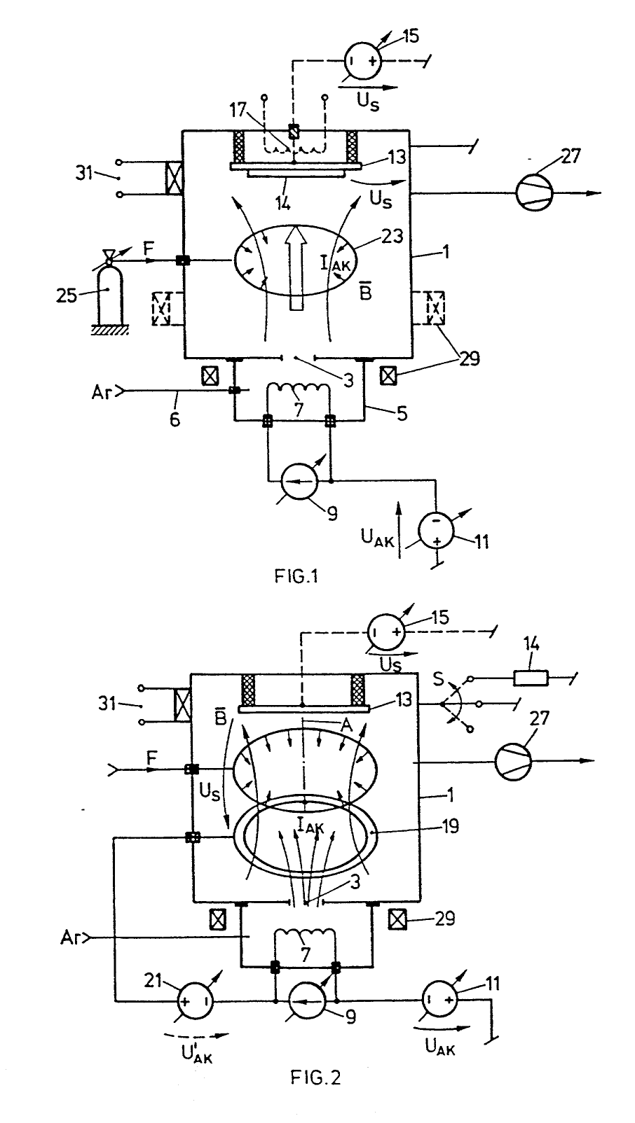

FIG. 2 is a schematic view of a second preferred embodiment of a system according to FIG. 1 with several operating variants;

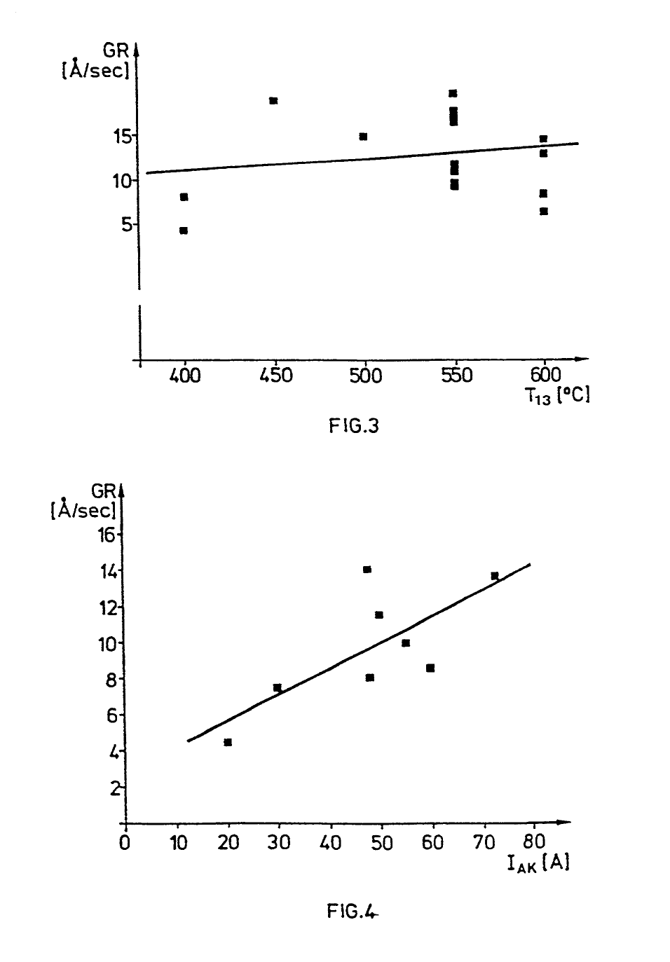

FIG. 3 is a view of the dependence of the growth rate on the wafer temperature during the operation of a system according to FIG. 2 for a silicon coating;

FIG. 4 is a view of the increase of the growth rate relative to the reactive gas flow GRr as a function of the discharge current;

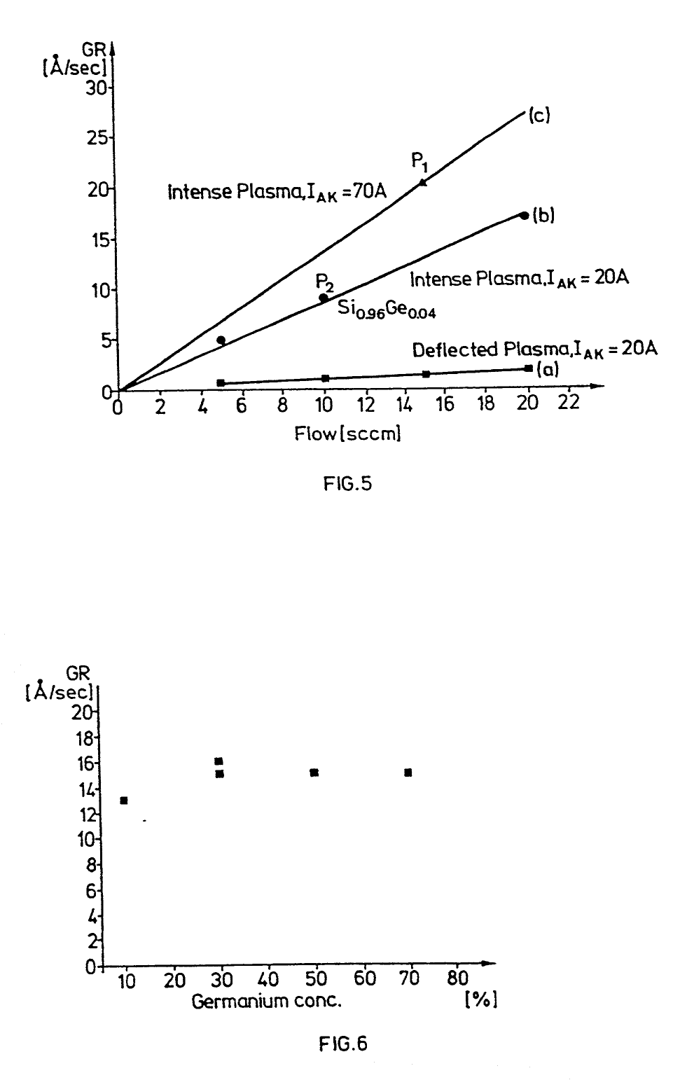

FIG. 5 is a view of the growth rate at different plasma densities in the area of the workpieces as a function of the reactive gas flow;

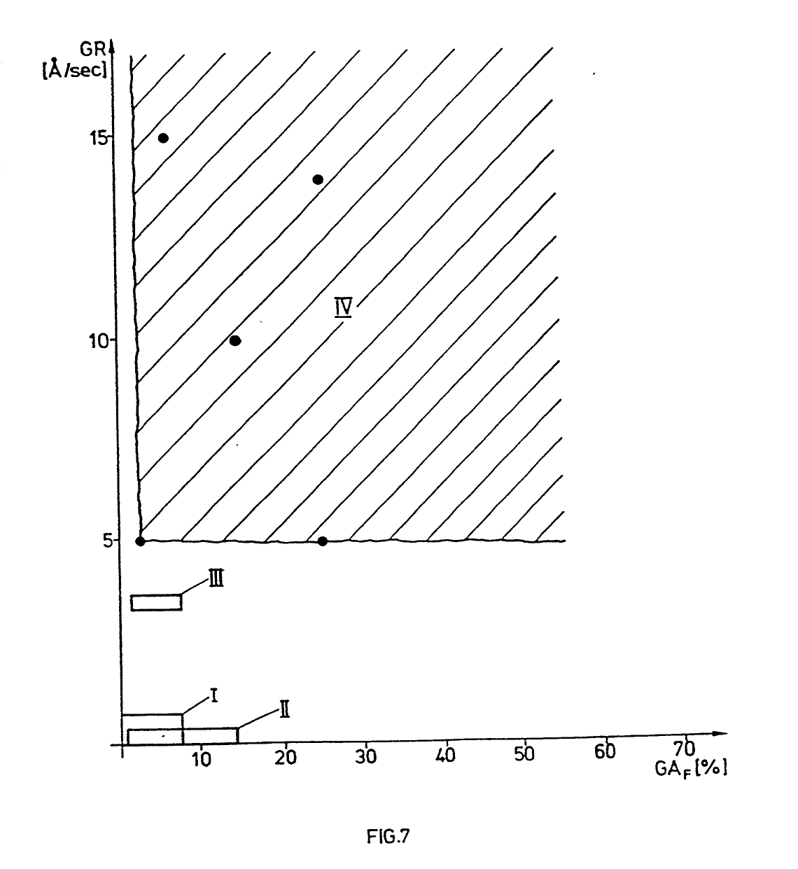

FIG. 6 is a view of the growth rate as a function of the germanium concentration on the deposited layer; and

FIG. 7 is a view of the results according to the prior art and according to the invention in the growth rate/gas utilization number field.

First, a system according to, for example, German Patent Document DE-OS 36 14 384 can definitely be used for implementing the method according to the invention if it is operated such that the conditions according to the invention are met.

According to FIG. 1, a first system, which is currently preferred, for implementing the method according to the invention, has a vacuum recipient 1 to which a cathode chamber 5 is flanged by way of a diaphragm 3. In a known manner, the cathode chamber 5 may be applied to the electric potential of the recipient 1, or the cathode chamber 5 may be insulated with respect to the recipient 1 and be applied to a potential deviating therefrom (not shown).

In the cathode chamber 5, a hot cathode 7—a filament—is provided, preferably heated directly by means of a heating current generator 9.

A workpiece holder 13, which is mounted in an insulated manner, is provided in the diaphragm axis A opposite the diaphragm 3 in the recipient 1. A workpiece heater 17 can be provided in the area of the workpiece holder 13. The recipient 1 is evacuated by means of a vacuum pump 27, preferably a turbo vacuum pump, in this case, particularly a turbo molecular pump. For observation and possibly for control purposes, sensors, such as a plasma monitor, etc. may be provided at a connection 31.

Concentrically to the axis A of the discharge with the discharge current I_{AK}, a gas injection ring 23 is provided as a reactive gas injection arrangement connected with a gas tank arrangement 25 for reactive gas which, by means of a controllable flow F (sccm), is admitted into the recipient.

In the cathode chamber 5, a connection 6 leads to a working gas tank, for example, containing Ar. By means of an electromagnet and/or permanent magnet arrangement 29, a magnetic field R is generated essentially concentrically to the axis A in the recipient, particularly also effectively in the area of the diaphragm 3. The field can preferably be displaced from the concentricity.

In its embodiment according to FIG. 1, the system is operated as follows:

The recipient wall corresponding to 1 is used as the anode of the discharge and for this purpose is switched to a reference potential, as illustrated, preferably to the ground. Correspondingly, by means of a preferably adjustable DC generator 11, the cathode 7 is connected to a (negative) potential. By way of the generator 11, the discharge voltage is U_{AK}; the discharge current I_{AK} flows between the cathode 7 and the recipient 1.

In a second operating variant of the system illustrated in FIG. 1, the workpiece holder 13 is applied to the voltage U_{S} by means of a DC bias generator 15.

FIG. 2 shows another preferred system according to the invention for implementing the method according to the invention. The same reference numbers as in FIG. 1 are used for identical parts. The system according to FIG. 2 differs as follows from the system illustrated and described in FIG. 1:

A ring-shaped auxiliary anode 19 is provided which is arranged concentrically to the discharge axis A.

The following operating modes can take place here:

As schematically illustrated by means of the variation switch S, the recipient wall of the recipient 1, as already illustrated in FIG. 1, is applied to a reference potential preferably a ground potential or, by way of an impedance element 14, preferably a resistor element, is anchored to a potential, preferably a reference potential, or is operated in a potential-floating manner. If the recipient 1 is applied to the reference potential, the auxiliary anode 19 is applied either to the potential of the recipient or is applied to voltage by means of a preferably adjustable DC generator 21.

If the recipient 1 is anchored by way of the impedance element 14 to the reference potential, the auxiliary anode is operated by means of the DC generator 21. The discharge voltage U_{AK} appears as illustrated by a broken line between the cathode 7 and the auxiliary anode 19. This is also true when the recipient wall 1 is operated in a potential-floating manner.

Currently, the operation of the system according to FIG. 2 is preferred with the recipient wall connected to the ground and the auxiliary electrode 19 as well as the workpiece holder 13 operated in a potential-controlled manner. In all system variants, the following adjustments are essential:

Total Pressure P_{I} in the Recipient:

10⁻⁴ mbar≦P_{T}≦10⁻¹ mbar

preferably

10⁻³ mbar<P_{T}≦10⁻² mbar

typically in the range of 5·10⁻³ mbar. This pressure is mainly ensured by the partial pressure of the working gas, preferably argon. As mentioned above, the vacuum pump 27, for this purpose is preferably constructed as a turbo vacuum pump, particularly a turbo molecular pump.

Working Gas Pressure P_{A}:

This pressure is selected as follows:

10⁻⁴ mbar≦P_{A}≦10⁻¹ mbar

preferably

10⁻¹ mbar≦P_{A}≦10⁻² mbar

Reactive Gas Partial Pressure P_{R}:

This pressure is preferably selected as follows:

10⁻¹ mbar<P_{R}≦10⁻¹ mbar

preferably

10⁻⁴ mbar≦P_{R}≦10⁻² mbar.

Particularly for silicon-containing and/or germanium-containing gases, partial pressures between 10⁻⁴ mbar and 25·10⁻¹ mbar are advisable. For promoting the (illegible—translator) (surface roughness), mainly for multiple-layer depositions and layers with doping, it is also advisable to additionally provide a hydrogen partial pressure in the order of form 10⁻⁴ to 10⁻¹ mbar, preferably of approximately 10⁻² mbar.

Gas Flows:

Argon: Largely dependent on recipient volume and cathode chamber volume, for the setting of the required partial pressure P_{A} and P_{T}.

Reactive gas flow: 1 to 100 sccm, particularly for silicon-containing and/or germanium-containing gases:

H₂: 1 to 100 sccm.

Discharge Voltage U_{AK}:

The discharge voltage, whether between the cathode 7 and the recipient 1 according to FIG. 1 or between the cathode 7, the recipient 1 and the auxiliary cathode 19 or between the cathode 7 and the auxiliary anode 19, is set as follows:

10 V≦U_{AK}≦80 V, preferably

20 V≦U_{AK}≦35 V.

Discharge Currents, I_{AK}:

These are selected as follows:

5 A≦I_{AK}≦400 A, preferably

20 A<I_{AK}≦100 A.

Workpiece Voltage U_{S}:

In each case, this voltage is selected below the sputtering threshold of the discharge. It is set in all cases as follows:

−25 V≦U_{S}≦+25 V,

preferably for Ga bonding, preferably for Si, Ge and their bonds

−20 V≦U_{S}≦20 V,

preferably negative, and in this case preferably

−15 V≦U_{S}<−3 V.

Current Density at the Site of the Workpiece Surfaces to Be Coated:

This density is first measured by means of a probe at the site where then the surface to be coated will be positioned. It is set relative to the probe surface at at least 0.05 A/cm², preferably at least 0.1 A/cm² to maximally discharge current/substrate surface.

This current density is measured and set as follows:

One or several probes are positioned at the site of the surface which will be coated and, with respect to the ground or anode potential, are connected to variable positive voltage. This voltage is increased until the measured current does not continue to rise. Relative to the probe surface, the measured current value indicates the entire current density. This current density will then be set to the required value by adjusting the discharge. The setting of the above-mentioned current density values can easily be carried out by means of the preferably set discharge currents I_{AK} between 5 and 400 A, or and preferably between 20 and 100 A.

The high flux of low-energy ions and electrons which impact on the workpiece is a characteristic of the method according to the invention, which is therefore abbreviated LEPECVD for “Low Energy Plasma Enhanced CVD”.

During the coating, silicon and/or germanium layers can be doped by the addition of a doping gas with an element of Group III or V of the Classification of Elements, such as phosphine, boroethane, arsine, etc. to form n-conductive or p-conductive layers. Thus, p/n semiconductor transitions can be produced in situ, for example, particularly economically for the manufacturing of solar cells.

When gallium layers or gallium bonding layers are deposited, these can be doped by using a doping gas with an element of Groups II or III or IV or VI of the Classification of Elements, for example, with Mg or Si.

By means of the anode 19 and/or the magnetic field B, the low-voltage discharge can be compressed and/or can be deflected with respect to the workpiece holder 13. As the result, the plasma density at the workpiece holder can be increased (rate) and/or can be varied over a large range (adjustment of the distribution) or can be wobbled or deflected in a controlled manner. By means of the heater 17, the workpieces and substrates can be heated independently of the ion and/or electron yield to approximately 800° C. By means of permanent and/or electromagnets, the magnet arrangement 29 generates the field B, preferably with a flux density of several 10 to several 100 gauss in the discharge space.

Because of the unusually low discharge voltages, as mentioned above, preferably in the range of from 20 to 35 V, a plasma potential of the discharge corresponding to (15) is obtained close to the anode potential. With respect to the potential, the workpiece or substrate potential can easily be adjusted such that the ion energies are below 15 eV, whereby ion-related damage during the layer growth on the workpiece can be completely avoided.

As mentioned above, a plasma density which is as high as possible must be endeavored on the workpiece. In the present case, the plasma density is defined by the current density at the workpiece surface. As indicated above, it is measured and set by means of probes in one calibrating operation.

The systems as illustrated schematically in FIGS. 1 and 2 currently are probably preferred embodiments. According to the method of the invention, they can definitely also be implemented on systems which are shown, for example, in German Patent Document DE-OS 36 14 384, if they are equipped and operated correspondingly. Up to now, the potential-controlled operation of the workpiece appears to be significant.

By means of a system as schematically illustrated in FIG. 2, R″-silicon monocrystal substrates are epitaxially coated with silicon or a silicon/germanium alloy. The volume of the recipient 1 amounted to 60 l.

The system was operated as follows:

Auxiliary anode 19 to potential of the recipient; workpiece holder 13 to controlled bias potential. Recipient as anode to ground.

The following operating point adjustments were made:

Workpiece Temperatures T_{S}:

In a plasma-induced manner, workpiece temperatures of only a few 100° C., thus, for example, of approximately 150° C., are obtained.

This is extremely advantageous for coating thermally critical substrates, such as organic substrates.

Higher desired temperatures are achieved by a separate heating. For producing Si and/or Ge layers and layers with Ge—Si bonding, workpiece temperatures T_{S}

300° C.≦T_{S}≦600° C.

are advisable; for Ga layers or Ga bonding layers:

300° C.≦T_{S}≦800° C.

are advisable.

Because the method is “cold”, the temperature selection is very flexible, depending on the layer material and the substrate material.

| | Flux (sccm) | Partial Pressure (mbar) |
|---|---|---|
| Ar | 50 | 6.8 × 10⁻³ |
| H₂ | 5 | 7 × 10⁻⁴ |
| SiH₄ | 10 | 10⁻³ |

Discharge Current I_{AK}: 70 A.
Discharge voltages U_{AK}: 25 V.
Substrate temperature: 550° V (heated by means of heater).

In a first test, the substrate temperature was varied by means of the heater 17. In this case, the other operating point parameters remain constant. FIG. 3 illustrates the result. This figure shows that the growth rate GR depends only very little on the workpiece temperature or substrate temperature T₁₃. The large scattering of the measured values is the result of the fact that, in the case of the test system, before each deposition, operating parameters in each case had to be adjusted again manually.

Based on the above-mentioned operating point values, the discharge current I_{AK} was now varied by adjusting the discharge voltage U_{AK} and optionally the variation of the cathode heating current. All other parameters were kept constant again. Although the discharge current I_{AK} also does not correspond directly to the charge carrier density or the plasma density on the surface to be coated, nevertheless, while the parameters otherwise remain constant, the plasma density, corresponding to the current density on the workpiece surface to be coated, is essentially proportional to the discharge current. The result illustrated in FIG. 4 therefore definitely shows the proportionality and the proportionality factor between the growth rate GR and the plasma density. This proportionality should last as long as the gas utilization does not exceed approximately 60% and saturation effects occur. As mentioned above, the plasma density can be affected, in addition to, for example, by the adjustment of the discharge current, also by focussing or defocussing the low voltage discharge or by its deflection. Here also, the relatively large scattering is the result of the approach during the setting of the discharge conditions.

FIG. 5, finally, is very informative. It is the result of tests in which, while the parameters were otherwise kept constant, the reactive gas flow F was varied, starting from the operating point 10 sccm. The straight line (a) was obtained with the low voltage discharge locally offset slightly with respect to the axis A of FIG. 1 by a magnetic field adjustment, which, on the substrate, resulted in a plasma density reduction or a lower rate, in the case of a discharge current I_{AK} of 20 A.

Curve (b) shows the rate while the discharge is not deflected and at I_{AK}=20 A. Finally, (c) shows the increased rate while the discharge is not deflected with I_{AK}=70 A.

As confirmed in FIG. 3, a GR of approximately 15 Å/sec. is obtained in the case of a reactive gas flow of 10 sccm at a temperature of the substrate of 550° C. and 70 A discharge current I_{AK}.

In the case of a discharge current of 70 A with a reactive gas flow of 10 sccm, this result is also confirmed by FIG. 4. In the case of a discharge current of 20 A, the GR decreases to approximately 6 Å/sec.

The results according to the invention will now be compared with the results of the prior art.

a) Comparison with APCVD (2)

From FIG. 5, the following is obtained, for example, for point P1:

GR≈1200 Å/min, compared with

GR≈2×10⁻² Å/min in the case of the APCVD.

From FIG. 5, the following value is obtained for point P1:

GR_{F} of 80 Å/(sccm.min)

The corresponding value in the case of APCVD amounts to:

GR_{F}≈2×10⁻⁴ Å/(sccm.min)

When, in the case of the LEPECVD according to the invention, the gas utilization number is calculated for a 3″ substrate, the following is obtained:

GA_{F}≈6, 11×10², corresponding to approximately (illegible).

In this case, it should be taken into account that this number becomes significantly better as the substrate surface becomes larger, for example, on 5″.

FIG. 7 shows the following results:

In Field I: for ABCVD, LPCVD, RPECVD;

in Field II: for UHVCVD

in Field III: for ECRCVD

in Field IV: according to the present invention.

They apply to temperatures≦600° C.

In this context, it should be stressed again that the approach according to the invention permits the coating of relatively large surfaces, whereby the gas utilization number GA_{P}, also rises.

If, analogously, the large growth rate GR, the growth rate per reactive gas flow unit GR_{F}, and the gas utilization number GA_{F} are compared with the corresponding number for CVD at atmospheric pressure conditions, drastic improvements occur according to the invention in every respect. If finally the results according to the present invention are compared with those which are obtained when a PECVD method is operated by means of low-voltage discharge according to German Patent Document DE-OS 36 14 384, it is found that astonishingly the growth rate of 1200 Å/min achieved according to the invention is significantly higher than the highest growth rates achieved by means of the previously known methods and that, in addition, the growth rate per reactive gas flow unit GR_{F} achieved according to the invention is virtually by two powers of ten higher.

It is therefore extremely surprising that by means of very specific operating conditions at the system, as they were known in principle from German Patent Document DE-OS 36 14 384, such improvements can be achieved, taking into account that the layers deposited according to the invention correspond to epitaxy conditions with respect to the density of defects.

This was examined in a very simple manner in that, in the case of the described operation of the system according to FIG. 2, with the indicated operating point parameters, when inserting a monocrystalline substrate, a high-quality epitaxy coating was achieved but, when an amorphous substrate was inserted, with the same operating point parameters, an amorphous coating was obtained.

Furthermore, the measuring point is illustrated at P2 in FIG. 5, if, instead of a pure Si layer, an SiGe epitaxy layer is deposited which contains 4% Ge.

As indicated by the above, in contrast to the above-explained findings, in the case of the approach according to the invention, the conditions will not change when a GE/Si alloy is deposited. This is confirmed by FIG. 6, where, as a function of the Ge content, the growth rate GR is indicated in % at the indicated operating points. This shows that the growth rate essentially does not change in a very large range of the Ge to Si ratio.

The approach according to the invention was primarily confirmed by means of attempts to deposit Se, Ge or Si/Ge alloy layers or GA and GA bonding layers, all in a doped and undoped condition.

By means of the approach according to the invention, in a combined manner, the highest layer quality is achieved while the deposition rates are very high and the efficiency is simultaneously very high as far as deposited layer material per admitted reactive gas quantity is concerned, and at low temperatures ≦600° C. Thus, the suggested approach is extremely well suited for industrial production, whether with respect to epitaxial layers or other layers of the highest quality.

1. Method for producing coated workpieces of a quality sufficient for epitaxy, characterized in that the workpiece is coated by means of PECVD using a DC discharge.

2. Method according to claim 1, characterized in that the coating takes place at a growth rate
GR≧150 Å/min
and with a gas utilization number of
1%≦GA_{F}≦90%.

3. Method according to claim 1, characterized in that the growth rate amounts to
GR≧300 Å/min, preferably
GR≧600 Å/min, particularly preferably
GR≧1′000 Å/min.

4. Method according to claim 3, characterized in that the gas utilization number is
GA_{F}≧5%.

5. Method according to one of claims 1 to 4, characterized in that the discharge is set such that, in the case of a probe measurement at the site where then the workpiece surface to be coated will be positioned, and on the same potential, a current density of at least 0.05 A/cm² probe surface is set, preferably of at least 0.1 A/cm² to a density of maximally the discharge current/substrate surface.

6. Method according to claim 5, characterized in that the measured current density is predominantly generated by electron incidence.

7. Method according to one of claims 1 to 6, characterized in that a discharge current I_{AK} is selected at
5 A≦I_{AK}≦400 A,
preferably at
20 A≦I_{AK}≦100 A.

8. Method according to one of claims 1 to 7, characterized in that the discharge voltage U_{AK} is selected at
10 V≦U_{AK}≦80 V,
preferably at
30 V≦U_{AK}≦35 V.

9. Method according to one of claims 1 to 8, characterized in that the reactive gas partial pressure P_{R} in the process space is selected at
10⁻¹ mbar≦P_{R}≦10⁻¹ mbar,
preferably at
10⁻⁴ mbar≦P_{R}≦10⁻² mbar.

10. Method according to one of claims 1 to 9, characterized in that the discharge is used predominantly as the electron source for the reactive gas dissociation.

11. Method according to one of claims 1 to 10, characterized in that a low-voltage discharge, preferably a hot cathode low voltage discharge, is used as the DC discharge.

12. Method according to one of claims 1 to 11, characterized in that, in the process space, a total pressure P_{T} is set which is
10⁻⁴ mbar≦P_{T}≦10⁻¹ mbar,
preferably
10⁻³ mbar≦P_{T}≦10⁻² mbar.

13. Method according to one of claims 1 to 12, characterized in that, in the recipient, a working gas partial pressure P_{A} is set which is
10⁻⁴ mbar≦P_{A}≦10⁻¹ mbar, preferably
10⁻³ mbar≦P_{A}≦10⁻² mbar.

14. Method according to one of claims 1 to 13, characterized in that the discharge voltage is applied between the discharge cathode and a vacuum recipient wall applied to a reference potential, preferably a ground potential.

15. Method according to claim 14, characterized in that, in the process space, the workpiece is operated
on a floating potential or
is connected to a switched-on bias potential.

16. Method according to claim 15, characterized in that the workpiece is operated on a voltage U₅ with respect to the discharge anode which is negative, preferably amounting to U₆≧−25 V, preferably amounting to between −15 V to −3 V.

17. Method according to one of claims 14 to 16, characterized in that, along the discharging distance, an auxiliary anode is provided, preferably in the form of a ring anode surrounding the discharge, and this ring anode is operated on a preferably adjustable voltage with respect to the discharge cathode which preferably is no larger than the discharge voltage.

18. Method according to one of claims 1 to 13, characterized in that, in the vacuum recipient, an anode, which in this respect is mounted in an insulated manner, is provided for the discharge, preferably in the form of a ring anode.

19. Method according to claim 18, characterized in that the workpiece in the process space is connected
to the floating potential or
to a switched-on bias potential.

20. Method according to claim 19, characterized in that the workpiece is operated with respect to the discharge cathode maximally at discharge voltage.

21. Method according to one of claims 18 to 20, characterized in that the vacuum recipient wall is operated
on the floating potential or
by way of an impedance element anchored to a reference potential.

22. Method according to one of claims 1 to 13, characterized in that the workpiece is operated with respect to the anode of the discharge at a voltage between −25 V and +25 V, preferably for GA bonds, preferably for Si, Ge or their bonds, preferably
−20 V ≦U_{S}≦+20 V,
in this case, preferably at a negative voltage.

23. Method according to one of claims 1 to 22, characterized in that the workpiece temperature is maintained at maximally 600° C., preferably between 300° C. and 600° C., preferably for Si, Ge or their bonds and preferably for Ga bonds between 300° and 800° C.

24. Method according to one of claims 1 to 23, characterized in that the coating takes place at a coating rate per reactive gas flow unit GR_{F,} which amounts to at least 7.5 Å/(sccm.min), preferably at least 40 Å/sccm.min), particularly at least 75 Å/(sccm.min).

25. Method according to one of claims 1 to 12, characterized in that the desired coating rate changes are carried out by an adjusting, which is essentially proportional thereto, of the reactive gas flow in the vacuum recipients.

26. Method according to one of claims 1 to 25, characterized in that the desired coating rate changes are carried out by an adjusting, which is essentially proportional thereto, of the discharge current density, preferably by adjusting the discharge current and/or the discharge voltage and/or by the deflection and/or by a bunching variation of the discharge with respect to the workpiece, the latter preferably electrostatically and/or magnetically.

27. Method according to one of claims 1 to 26, characterized in that the workpiece is heated independently of the discharge.

28. Use of a PECVD method with DC discharge for producing epitaxy layers.

29. Use of the method according to one of claims 1 to 17 and use according to claim 28 for the production of substrates with a semiconductor layer.

30. Use according to claim 29 for the production of substrates with a semiconductor epitaxy layer or a polycrystalline or an amorphous semiconductor layer, preferably controlled by the uncoated substrate, particularly its surface characteristics.

31. Use according to one of claims 28 to 30 for the production of substrates with a silicon and/or germanium layer or an Si/Ge alloy layer, preferably doped with at least one element of Groups III and/or V of the Classification of Elements.

32. Use according to one of claims 28 to 30 for the production of substrates with a Ga layer or a Ga bond layer, preferably doped with at least one element of Groups II, III, IV or VI of the Classification of Elements, for example, with Mg or Si.

33. Use according to one of claims 28 to 32, characterized in that at least one Si-containing and/or Ge-containing gas is used as the reactive gas and preferably additionally hydrogen gas is fed into the reaction space.

34. Use according to one of claims 28 to 33 for the workpiece coating with coating rates per reactive gas flow unit, GR_{F} of at least 7.5 Å/(sccm.min), preferably of at least 40 Å/(sccm.min), preferably even of at least 75 Å/sccm.min).

35. Use according to claim 34 for the coating of substrates at substrate temperatures below 600° C., preferably between 300° C. and 600° C. for Si, Ge and their bonds, preferably between 300° and 800°, for preferably Ga bonds.

36. System for implementing the method according to one of claims 1 to 26 having a vacuum recipient, coupled thereto by means of a diaphragm, a cathode chamber with at least one hot cathode and a workpiece holder arranged in the recipient as well as an anode arrangement, the workpiece holder being mounted in the recipient in an electrically insulated manner.

37. System according to claim 36, characterized in that the workpiece holder with respect to the anode can be connected to adjustable voltage or is potential-floating, the recipient housing being connected to an anode potential, and the cathode being placeable with respect to the anode potential on cathodic a potential, preferably between 10 and 80 V, in this case particularly preferably between 20 and 35 V, preferably the workpiece holder, relative to the anode potential, being adjustable maximally by ±25 V.

38. System according to claim 36 and 37, characterized in that the anode arrangement for the discharge comprises the vacuum recipient wall or the anode arrangement is mounted in the recipient in an insulated manner.

39. System according to claim 38, characterized in that the workpiece holder is potential-floating and is arranged such that its voltage with respect to the anode arrangement is set not more negatively than −25 V, preferably to −3 V to −15 V.

40. System according to claim 38, characterized in that the workpiece holder can be placed by means of a preferably adjustable bias source with respect to the anode arrangement on a voltage of −25 V to +25 V, preferably on a negative voltage, preferably of −15 V to −3 V.

41. System according to one of claims 36 to 40, characterized in that an auxiliary anode is provided, preferably in the form of a ring anode which is arranged concentrically to the axis of the diaphragm and which, with respect to the recipient wall, can be connected to the same or a different potential or is connected to it.

42. System according to one of claims 36 to 41, characterized in that the recipient wall is potential-floating or is anchored by way of an impedance element, preferably a resistor element, to a reference potential.

43. System according to one of claims 36 to 42, characterized in that, between the hot cathode and at least one part of the anode arrangement, a voltage U_{AK} of
10 V≦U_{AK}≦80 V, preferably
20 V≦U_{AK}≦35 V
is set.

44. System according to one of claims 36 to 43, characterized in that, between the workpiece holder and maximal potential on the anode arrangement a voltage U_{S} of
−25 V≦U_{S}≦+25 V
is set, preferably a negative voltage, preferably of
−15 V≦U_{S}≦−3 V.

45. System according to one of claims 36 to 44, characterized in that a gas feed pipe leads into the cathode chamber and is connected with a working gas tank, preferably an argon gas tank.

46. System according to one of claims 36 to 46, characterized in that, essentially concentrically with respect to the diaphragm axis, a magnet arrangement is provided, for generating a magnetic field in the recipient which is coaxial to the diaphragm axis or is offset thereto, the magnet arrangement comprising permanent magnets and/or at least one coil arrangement.

47. System according to one of claims 36 to 46, characterized in that the recipient is connected to a turbo vacuum pump, preferably a turbo molecular pump.

48. System according to one of claims 36 to 47, characterized in that the hot cathode supplies an electron current of 5 to 400 A, preferably between 20 and 100 A.

49. System according to one of claims 36 to 48, characterized in that the workpiece holder is arranged at the side of the highest electron density of the discharge, preferably essentially concentrically to the diaphragm axis in the recipient.

50. System according to one of claims 36 to 49, characterized in that the recipient is connected with a gas tank arrangement which contains an Si-containing and/or Ge-containing gas or a GA-containing gas, preferably additionally with H₂.

51. Use of the system according to one of claims 36 to 50, according to claims 28 to 35.

52. Use of a PECVD coating method with a DC discharge for the growth of epitaxy layers.

53. Method for operating a PECVD system according to one of claims 36 to 50 such that, by defining the workpiece surface properties, such as the crystal structure, it is controlled whether a polycrystalline, an amorphous or an epitaxial layer is formed.

54. Use of the method according to one of claims 1 to 27 or of a system according to one of claims 36 to 50 for the production of solar cells.
